(19) United States
(12) Patent Application Publication
(10) Pub. No.: US 2008/0130248 A1
(43) Pub. Date: Jun. 5, 2008

(54) CASING

(75) Inventors: Jung-Chi Chen, Hsinchu (TW); Chih-Hui Chang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CORETRONIC CORPORATION, Hsinchu (TW)

(21) Appl. No.: 11/836,148

(22) Filed: Aug. 9, 2007

(30) Foreign Application Priority Data
Dec. 4, 2006 (TW) 95144941

(51) Int. Cl. H05K 5/03

(52) U.S. Cl. 361/732

(57) ABSTRACT

A casing adapted for packing an electronic device is provided. The casing includes a shell, a cover, and a thermal switch. The shell has an assembly opening, and the cover is adapted for being installed to the assembly opening. The shell and the cover surround the electronic device. The thermal switch is disposed in one of the shell and the cover. When the thermal switch is heated by the electronic device and the temperature thereof rises, the deformation of the thermal switch forms the interference between the cover and the shell so as to prevent the cover being departed from the shell. Therefore, the present invention is capable of avoiding the user from being scalded by the electronic device.

### CROSS-REFERENCE TO RELATED APPLICATION

This application claims the priority benefit of Taiwan application serial no. 95144941, filed Dec. 4, 2006. All disclosure of the Taiwan application is incorporated herein by reference.

### BACKGROUND OF THE INVENTION

1. Field of the Invention

The present invention relates to a casing, and more particularly to a casing for preventing a cover being departed from a shell at a high temperature.

2. Description of Related Art

A conventional casing for an electronic device generally has a detachable cover, so as to facilitate maintainers to maintain the electronic device. For example, a light cover is disposed near a light source module of a projection apparatus, thus being convenient for the maintainers to maintain the light source module.

In a common projection apparatus, the light source module is mostly made of metal, and when the projection apparatus is in operation, the metal will be at a high temperature far exceeding the body temperature of human being as the metal continuously accumulates energy under the irradiation of the light source. Therefore, after the projection apparatus is turned off, if a user immediately detaches the light cover for maintaining the light source module, the user is very likely to be scalded by the high temperature remained on the light source module. In order to avoid the above circumstance, a warning tag is attached to the current light source module, such that the user may notice the warning tag after detaching the light cover, thereby reducing the possibility of being scalded for the user.

However, as the user cannot determine the temperature of the light source module without detaching the cover, the warning tag attached to the light source module may not prevent the user from being scalded.

### SUMMARY OF THE INVENTION

The present invention is directed to provide a casing, the cover of which cannot be detached by a user when the temperature of an electronic device is over high, so as to prevent the user from being scalded by the electronic device.

The present invention can be further understood from the technical features disclosed by the present invention.

An embodiment of the present invention provides a casing adapted for packing an electronic device. The casing comprises a shell, a cover, and a thermal switch. The shell has an assembly opening, and the cover is assembled to the assembly opening, wherein the shell and the cover surround the electronic device. The thermal switch is disposed in one of the shell and the cover. When the thermal switch is heated by the electronic device and the temperature thereof rises, the deformation of the thermal switch results in the interference between the cover and the shell, so as to prevent the cover being departed from the shell.

In the casing according to a preferred embodiment of the present invention, the electronic device comprises a projection apparatus having a light source module, and the cover comprises a light cover.

The casing according to a preferred embodiment of the present invention, further comprises a hook disposed on the other one of the shell and the cover, wherein the hook protrudes towards the thermal switch, and corresponds to the thermal switch.

In the casing according to a preferred embodiment of the present invention, the hook is disposed adjacent to the edge of the cover, and the thermal switch is disposed adjacent to the edge of the assembly opening.

In the casing according to a preferred embodiment of the present invention, the thermal switch is disposed adjacent to the edge of the cover, and the hook is disposed adjacent to the edge of the assembly opening.

In the casing according to a preferred embodiment of the present invention, the thermal switch comprises a first column and a second column. The first column is connected to the second column, and the thermal expansion coefficient of the first column is smaller than that of the second column. The first column is disposed adjacent to the edge of the assembly opening, while the second column is disposed away from the edge of the assembly opening, and the first column is adapted for extending towards the direction of the edge of the assembly opening.

In the casing according to a preferred embodiment of the present invention, the material of the first column is copper, and the material of the second column is aluminum.

In the casing according to a preferred embodiment of the present invention, the thermal switch is made of a single material. One end of the thermal switch is connected to a connecting portion of the cover to form a fixed end, and the other end is a free end, wherein the free end is adapted for being inserted into the shell to prevent the cover being departed from the shell.

In the present invention, due to the heat expansion and cold contraction principle, interference is formed between the cover and the shell after the thermal switch is heated, so as to prevent the cover being departed from the shell. Therefore, the user cannot detach the cover of the casing when the temperature of the electronic device is too high, thus avoiding the user from being scalded by the electronic device.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a schematic exploded perspective view of a projection apparatus according to a first embodiment of the present invention.

FIG. 2A is a schematic top view of the thermal switch in FIG. 1 before being heated by the light source module.

FIG. 2B is a sectional view taken along I-I′ in FIG. 2A.

FIG. 3A is a schematic top view of the thermal switch in FIG. 1 after being heated by the light source module.

FIG. 3B is a sectional view taken along II-II′ in FIG. 3A.

FIG. 4A is a schematic top view of the thermal switch according to a second embodiment before being heated by the light source module.

FIG. 4B is a sectional view taken along III-III′ in FIG. 4A.

FIG. 5A is a schematic top view of the thermal switch according to a second embodiment after being heated by the light source module.

FIG. 5B is a sectional view taken along IV-IV′ in FIG. 5A.

FIG. 6A is a schematic top view of the thermal switch according to a third embodiment before being heated by the light source module.

FIG. 6B is a schematic top view of the thermal switch in FIG. 6A after being heated by the light source module.

### DESCRIPTION OF EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” and variations thereof herein are used broadly and encompass direct and indirect connections. Similarly, “adjacent to” and variations thereof herein are used broadly and encompass directly and indirectly “adjacent to”. Therefore, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

The present invention provides a casing adapted for packing an electronic device, wherein the casing includes a cover and a thermal switch. When the thermal switch is heated by the electronic device and the temperature thereof rises, the thermal switch is deformed to prevent the cover from being detached. In order to illustrate the spirit of the present invention, a preferred embodiment is provided by taking the casing of a projection apparatus as an example, and thus, the electronic device is, for example, a projection apparatus, particularly a projection apparatus having a light source module. When the projection apparatus is in operation, the light source module generates a high temperature. Therefore, the thermal switch is heated by the light source module and is deformed as the temperature thereof rises, such that the cover cannot be detached. However, the present invention is not limited to the casing of a projection apparatus, but can be other casings of electronic devices which are of a high temperature, such as the casing of a light cover or back light module.

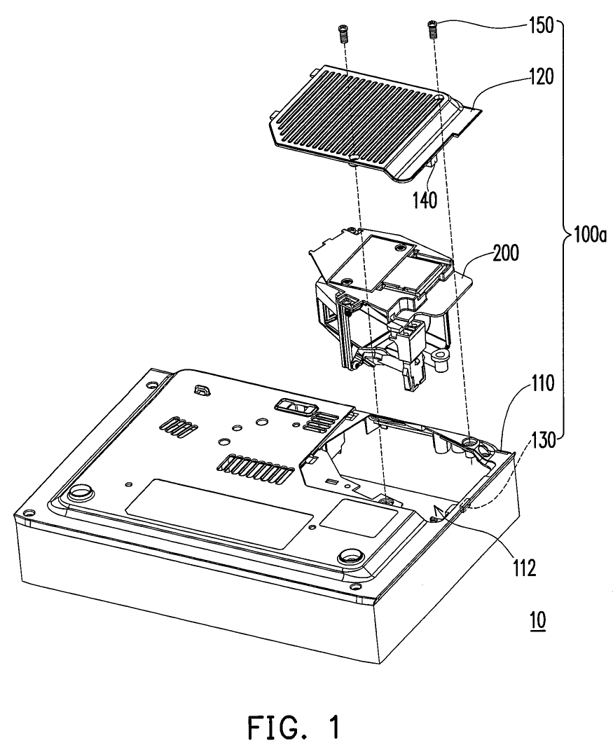

FIG. 1 is a schematic exploded perspective view of a projection apparatus according to a first embodiment of the present invention. In order to simplify the figure, only a casing 100a and a light source module 200 of a projection apparatus 10 are shown in FIG. 1. Referring to FIG. 1, the casing 100a includes a shell 110, a cover 120, and a thermal switch 130. The shell 110 has an assembly opening 112, and the cover 120 is assembled to the assembly opening 112. Moreover, when the cover 120 is assembled to the assembly opening 112, the shell 110 and the cover 120 surround the light source module 200. In addition, the thermal switch 130 is disposed in the shell 110. When the thermal switch 130 is heated by the light source module 200 and the temperature thereof rises, the deformation of the thermal switch 130 results in the interference between the thermal switch 130 and the cover 120, so as to prevent the cover 120 being departed from the shell 110.

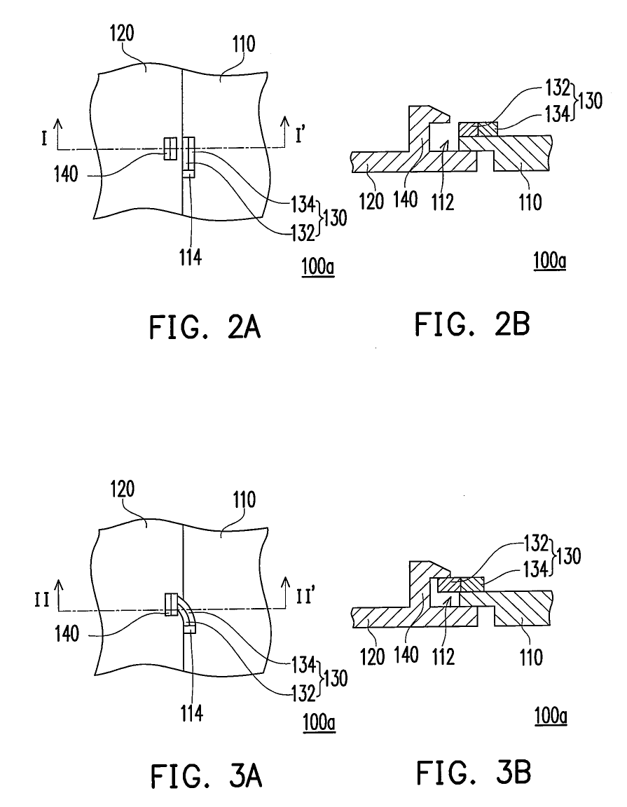

FIG. 2A is a schematic top view of the thermal switch in FIG. 1 before being heated by the light source module, and FIG. 2B is a sectional view taken along I-I′ in FIG. 2A. In addition, FIG. 3A is a schematic top view of the thermal switch in FIG. 1 after being heated by the light source module, and FIG. 3B is a sectional view taken along II-II′ in FIG. 3A. Referring to FIG. 2A and FIG. 2B, in the first embodiment of the present invention, the thermal switch 130 is disposed adjacent to the edge of the assembly opening 112, and the casing 100a further includes a hook 140 disposed on the cover 120. The hook 140 protrudes towards the thermal switch 130, and is disposed adjacent to the edge of the cover 120. Moreover, the hook 140 corresponds to the thermal switch 130. Further, one end of the thermal switch 130 is connected to a connecting portion 114 of the shell 110 to form a fixed end, and the other end of the thermal switch 130 forms a free end. Referring to FIG. 3A and FIG. 3B, when the thermal switch 130 is heated by the light source module 200 and the temperature thereof rises, the free end of the thermal switch 130 extends (e.g., bends) towards the assembly opening 112, and is inserted into the hook 140. At this point, the cover 120 cannot depart from the shell 110 due to the interference between the hook 140 and the thermal switch 130.

In particular, the thermal switch 130 includes a first column 132 and a second column 134, and the first column 132 is connected to the second column 134. The first column 132 is disposed adjacent to the assembly opening 112, while the second column 134 is disposed away from the assembly opening 112, and the edge of the first column 132 is aligned with the edge of the assembly opening 112 or inside the edge of the assembly opening 112. Moreover, the thermal expansion coefficient of the first column 132 must be smaller than that of the second column 134. When the thermal switch 130 is heated by the light source module 200 and the temperature thereof rises, the first column 132 and the second column 134 expand due to the heat. However, as the thermal expansion coefficient of the first column 132 is smaller than that of the second column 134, the expansion of the first column 132 is smaller than that of the second column 134. At this point, as the first column 132 is connected to the second column 134, the thermal switch 130 may extend (e.g., bend) towards the direction of the edge of the assembly opening 112, such that the first column 132 is inserted into the assembly opening 112, thereby preventing the cover 120 being departed from the shell 110.

In the preferred embodiment of the present invention, the material of the first column 132 is, for example, copper, and the material of the second column 134 is, for example, aluminum. The expansion coefficient of copper is smaller than that of aluminum, and thus when the thermal switch 130 is heated, the expansion of the first column 132 is smaller than that of the second column 134. Therefore, the thermal switch 130 extends towards the direction of the edge of the assembly opening 112, so as to prevent the cover 120 being departed from the shell 110.

It can be known from the above embodiment that, when the projection apparatus 10 is in use, the temperature of the thermal switch 130 rises as the temperature of the light source module 200 rises, such that the thermal switch 130 is deformed to prevent the cover 120 being departed from the shell 110. Moreover, after the projection apparatus 10 is turned off, the temperature of the thermal switch 130 gradually reduces from a high temperature to the room temperature along with the temperature of the light source module 200, and the thermal switch 130 gradually restores its original shape. In this embodiment, the insert length of the thermal switch 130 inserted into the hook depends on the temperature of the thermal switch, the lengths, thermal expansion coefficient values of the first column 132 and the second column 134, and thermal expansion coefficient difference between the first column 132 and the second column 134.

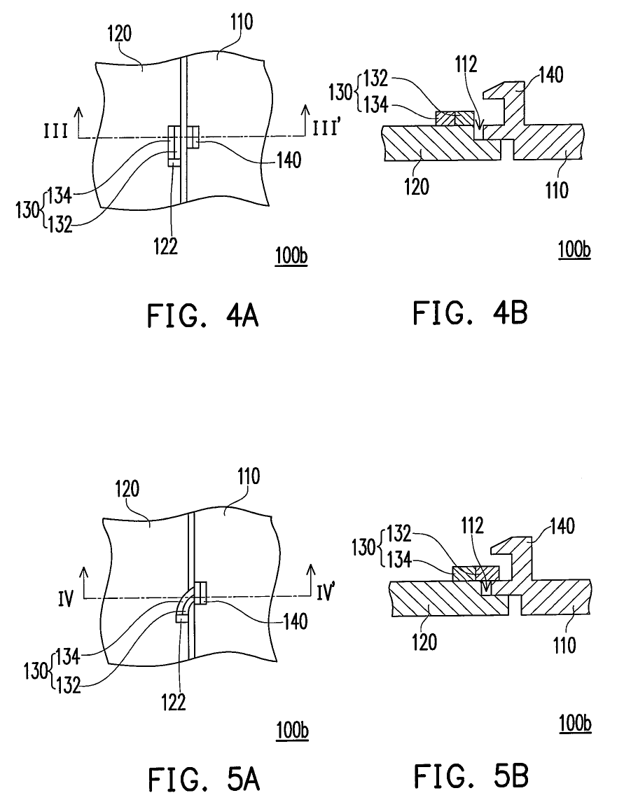

FIG. 4A is a schematic top view of the thermal switch according to a second embodiment before being heated by the light source module, and FIG. 4B is a sectional view taken along III-III′ in FIG. 4A. Moreover, FIG. 5A is a schematic top view of the thermal switch according to a second embodiment after being heated by the light source module, and FIG. 5B is a sectional view taken along IV-IV′ in FIG. 5A. Referring to FIG. 4A to FIG. 5B, the structure of the casing 100b is substantially the same as that of the casing 100a in FIG. 2A to FIG. 3B, except that the thermal switch 130 is disposed in the cover 120, and located between the cover 120 and the light source module 200. Therefore, the thermal switch 130 is disposed adjacent to the edge of the cover 120, and the shell 110 has a hook 140. The hook 140 protrudes towards the thermal switch 130, and is adjacent to the edge of the assembly opening 112. Moreover, the hook 140 corresponds to the thermal switch 130. Further, one end of the thermal switch 130 is connected to a connecting portion 122 of the cover 120 to form a fixed end. However, the method of preventing the cover 120 being departed from the shell 110 through the deformation of the thermal switch 130 when heated, which forms interference between the thermal switch 130 and the hook 140, is the same as that of the first embodiment, and will not be described herein again.

In this embodiment, the thermal switch 130 is connected to the cover 120. Moreover, the cover 120 and the deformed thermal switch 130 may hold the cover 120 on the shell 110. Therefore, a hook 140 is not required by the shell 110 in this embodiment.

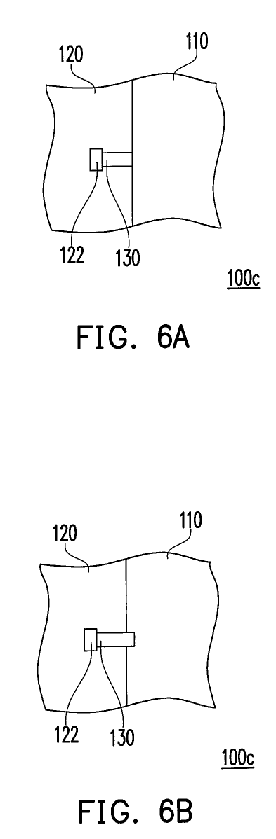

FIG. 6A is a schematic top view of the thermal switch according to a third embodiment before being heated by the light source module, and FIG. 6B is a schematic top view of the thermal switch in FIG. 6A after being heated by the light source module. Referring to FIG. 6A to FIG. 6B, the structure of the casing 100c is substantially the same as that of the casing 100b in FIG. 4A to FIG. 5B, except that the thermal switch 130 is made of a single material, one end of the thermal switch 130 is connected to the connecting portion 122 of the cover 120 to form a fixed end, while the other end of the thermal switch 130 is a free end, and the free end of the thermal switch 130 is aligned with the edge of the cover 120 or inside the edge of the cover 120. When the thermal switch 130 is heated by the light source module 200 and the temperature thereof rises, the thermal switch 130 is deformed, such that the free end is inserted into the shell 110 to prevent the cover 120 being departed from the shell 110.

Similarly, in this embodiment, the thermal switch 130 is connected to the cover 120. Moreover, the cover 120 and the deformed thermal switch 130 may hold the cover 120 on the shell 110. Therefore, a hook 140 is not required by the shell 110 of this embodiment.

In addition, referring to FIG. 1 again, in an embodiment, the casing 100a may further include a locking element 150, and the cover 120 is connected to the shell 110 or the light source module 200 through the locking element 150. The locking element 150 is, for example, screws or other locking element.

In view of the above, the temperature of the thermal switch of the present invention rises as the temperature of the electronic device rises, such that the thermal switch is deformed to prevent the cover being departing from the shell. Moreover, the temperature of the thermal switch also gradually reduces from a high temperature to the room temperature along with the temperature of the electronic device, such that the thermal switch gradually restores to its original shape. Therefore, the cover of the present invention cannot be detached when the temperature of the electronic device is over high, thereby avoiding the user from being scalded by the electronic device after detaching the cover.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A casing, for an electronic device, the casing comprising:
a shell, having an assembly opening;
a cover, assembled to the assembly opening, wherein the shell and the cover surround the electronic device; and
a thermal switch, disposed in one of the shell and the cover, wherein when the thermal switch is heated by the electronic device and the temperature thereof rises, the deformation of the thermal switch results in the interference between the cover and the shell to prevent the cover being departed from the shell.

2. The casing as claimed in claim 1, wherein the electronic device comprises a projection apparatus having a light source module, and the cover comprises a light cover.

3. The casing as claimed in claim 1, further comprising a hook, disposed in the other one of the shell and the cover, wherein the hook protrudes towards the thermal switch, and corresponds to the thermal switch.

4. The casing as claimed in claim 3, wherein the hook is disposed adjacent to the edge of the cover, and the thermal switch is disposed adjacent to the edge of the assembly opening.

5. The casing as claimed in claim 3, wherein the thermal switch is disposed adjacent to the edge of the cover, and the hook is disposed adjacent to the edge of the assembly opening.

6. The casing as claimed in claim 1, wherein the thermal switch comprises:
a first column; and
a second column, connected to the first column, wherein the thermal expansion coefficient of the first column is smaller than that of the second column, the first column is disposed adjacent to the edge of the assembly opening, the second column is disposed away from the edge of the assembly opening, and the first column is adapted for extending towards the edge of the assembly opening.

7. The casing as claimed in claim 6, wherein the material of the first column is copper, and the material of the second column is aluminum.

8. The casing as claimed in claim 1, wherein the thermal switch is made of a single material, one end of the thermal switch is connected to a connecting portion of the cover to form a fixed end, and the other end of the thermal switch is a free end, wherein the free end is adapted for being inserted into the shell, whereby preventing the cover being departed from the shell.
